(19) United States
(12) Patent Application Publication
(10) Pub. No.: US 2025/0391447 A1
(43) Pub. Date: Dec. 25, 2025

(54) HETEROGENEOUS INTEGRATED CIRCUITS WITH VOLTAGE BOOSTER CIRCUITS, INCLUDING HETEROGENEOUS INTEGRATED CIRCUITS WITH INDUCTOR-BASED PUMPS, AND ASSOCIATED SYSTEMS, DEVICES, AND METHODS

(71) Applicant: Micron Technology, Inc., Boise, ID (US)

(72) Inventors: Lingming Yang, Meridian, ID (US); Raghukiran Sreeramaneni, Frisco, TX (US); Nevil N. Gajera, Meridian, ID (US); Srivatsan Venkatesan, Sandy, UT (US)

(21) Appl. No.: 19/222,911

(22) Filed: May 29, 2025

Related U.S. Application Data
(60) Provisional application No. 63/663,058, filed on Jun. 21, 2024.

(51) Int. Cl. G11C 5/14; H01L 25/065; H01L 25/18; H02M 3/00; H10B 80/00

(52) U.S. Cl. CPC G11C 5/145; H01L 25/0657; H01L 25/18; H10B 80/00; H01L 2225/06541; H02M 3/003

(57) ABSTRACT

Heterogeneous integrated circuits with voltage booster circuits (e.g., inductor-based pumps) and associated systems and methods, are disclosed herein. In one embodiment, a heterogeneous integrated circuit includes (a) one or more first dies of a first type and (b) a second die of a second type different from the first type. The first die(s) can be integrated with (e.g., stacked on, bonded to, interconnected with) the second die. The heterogeneous integrated circuit can further include a voltage booster circuit, such as an inductor-based pump. The inductor-based pump can (i) include an inductor positioned within the second die, (ii) include an input configured to receive a first voltage, and (iii) include an output coupled to the first die(s). The inductor-based pump can be configured to (a) boost the first voltage to a second voltage greater than the first voltage and (b) output the second voltage at the output.

### CROSS-REFERENCE TO RELATED APPLICATION(S)

The present application claims priority to U.S. Provisional Patent Application No. 63/663,058, filed Jun. 21, 2024, the disclosure of which is incorporated herein by reference in its entirety.

### TECHNICAL FIELD

The present technology is generally related to semiconductor devices. For example, several embodiments of the present technology relate to heterogeneous integrated circuits with voltage booster circuits (e.g., inductor-based pumps or other suitable step-up voltage circuits), and associated systems, devices, and methods.

### BACKGROUND

An electronic apparatus (e.g., a processor, a memory device, a memory system, or a combination thereof) can include one or more semiconductor circuits configured to store and/or process information. For example, the apparatus can include a memory device, such as a volatile memory device, a non-volatile memory device, or a combination device. Memory devices, such as dynamic random-access memory (DRAM), NAND memory, and/or high-bandwidth memory (HBM), can utilize electrical energy to store and access data.

With technological advancements in embedded systems and increasing applications, the market is continuously looking for faster, more efficient, and smaller devices. To meet market demands, the semiconductor devices are being pushed to the limit with various improvements. Improving devices, generally, may include increasing circuit density, increasing circuit capacity, increasing operating speeds (or otherwise reducing operational latency), increasing reliability, increasing data retention, reducing power consumption, increasing energy efficiency, or reducing manufacturing costs, among other metrics. Attempts, however, to meet the market demands, such as by increasing energy efficiency, can often introduce challenges in other aspects, such as maintaining or reducing device size or footprint.

### BRIEF DESCRIPTION OF THE DRAWINGS

Many aspects of the present disclosure can be better understood with reference to the following drawings. The components in the drawings are not necessarily to scale. Instead, emphasis is placed on illustrating clearly the principles of the present disclosure. The drawings should not be taken to limit the disclosure to the specific embodiments depicted, but are for explanation and understanding only.

FIG. 1 is a partially schematic, cross-sectional side view of a heterogeneous integrated circuit configured in accordance with various embodiments of the present technology.

FIG. 2 is a partially schematic, cross-sectional side view of a system-in-package (SiP) device that includes a heterogeneous integrated circuit configured in accordance with various embodiments of the present technology.

FIG. 3A is a partially schematic, cross-sectional side view of a heterogeneous integrated circuit configured in accordance with various embodiments of the present technology.

FIG. 3B is a partially schematic diagram of an inductor-based pump configured in accordance with various embodiments of the present technology.

FIG. 4A is a partially schematic, cross-sectional side view of another heterogeneous integrated circuit configured in accordance with various embodiments of the present technology.

FIG. 4B is a partially schematic diagram of another inductor-based pump configured in accordance with various embodiments of the present technology.

FIG. 5A is a partially schematic, cross-sectional side view of still another heterogeneous integrated circuit configured in accordance with various embodiments of the present technology.

FIG. 5B is a partially schematic diagram of still another inductor-based pump configured in accordance with various embodiments of the present technology.

FIG. 6 is a flow diagram illustrating a method of operating a heterogenous integrated circuit in accordance with various embodiments of the present technology.

### DETAILED DESCRIPTION

As described in more detail below, the present disclosure is generally directed to heterogeneous integrated circuits that employ voltage booster circuits (e.g., in lieu of charge pumps) to boost voltage levels to requisite voltage levels. A heterogeneous integrated circuit (also referred to herein as a “heterogeneous integrated device,” a “heterogeneous stacked device,” a “heterogeneous device,” and the like) is a circuit or device that includes two or more different circuits or chips packaged together. Examples of heterogeneous integrated circuits include HBM cubes, HBM devices, hybrid memory cubes, chiplets, and other devices in which one or more first circuits (e.g., memory dies) are packaged together with (e.g., are bonded to, stacked over, interconnected with) one or more second, different circuits (e.g., host devices, such as central processing units (CPUs), graphics processing units (GPUs), or tensor processing units (TPUs); integrated circuits (ICs); or base/interface dies).

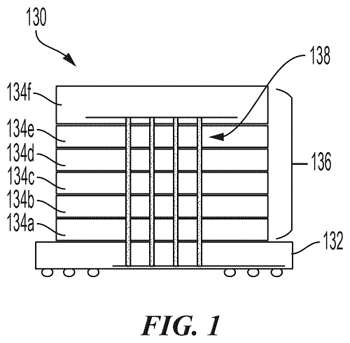

Specific details of several embodiments of the present technology are described herein with reference to FIGS. 1-6. For the sake of clarity and example, the present technology is primarily described below in the context of heterogeneous integrated circuits that include memory dies packaged with (e.g., stacked over) an interface die, integrated circuit, or host device (e.g., CPU, GPU, TPU). In addition, the memory dies of the heterogeneous integrated circuits are primarily described below in the context of (a) memory dies incorporating DRAM storage elements and/or (b) memory dies incorporating NAND storage elements. Heterogeneous integrated circuits configured in accordance with other embodiments of the present technology, however, can include (a) other types of circuits (e.g., non-memory dies, non-processing circuits); and/or (b) memory dies including other types of storage elements (in addition to or in lieu of DRAM storage elements and/or NAND storage elements), such as static random-access memory (SRAM) storage elements, NOR storage elements, phase change memory (PCM) storage elements, ferroelectric random-access memory (FeRAM) storage elements, resistive random-access memory (RRAM) storage elements, and/or magnetic random-access memory (MRAM) storage elements, among others. Moreover, a person of ordinary skill in the art will understand that embodiments of the present technology can have different configurations, components, and/or procedures than those shown or described herein, and/or that these and other embodiments can be without several of the configurations, components, and/or procedures shown or described herein without deviating from the present technology.

As used herein, the terms “vertical,” “lateral,” “upper,” “lower,” “top,” and “bottom” can refer to relative directions or positions of features in systems, devices, and circuits in view of the orientations shown in the drawings. For example, “bottom” can refer to a feature positioned closer to the bottom of a page than another feature. These terms, however, should be construed broadly to include systems, devices, and circuits having other orientations, such as inverted or inclined orientations where top/bottom, over/under, above/below, up/down and left/right can be interchanged depending on the orientation.

Many circuits require voltage levels higher than those supplied by power supplies. For example, DRAM memory dies and NAND memory dies commonly require voltages on the order of 3.3V and 12V, respectively, while power supplies commonly provide these dies with voltages on the order of 1.8V. Therefore, these circuits commonly employ charge pumps to boost voltage levels supplied by the default power supplies to requisite voltage levels. Such charge pump circuits typically include (a) one or more capacitors and (b) one or more switches arranged in two or more stages. The switches are clock-controlled to charge and discharge the capacitors and thereby manipulate an input voltage level to a desired output voltage level.

The process of charging and discharging capacitors of a charge pump, however, inherently results in energy loss. Thus, charge pumps are generally less energy efficient than other types of power converters, such as buck or boost converters. In addition, charge pumps often have a limited output current capability, meaning that they are not suitable for (and can be a drawback when used in) power-sensitive applications. Furthermore, an output voltage generated by a charge pump can be relatively unstable, especially under varying load conditions.

To address these concerns, the present technology is generally directed to heterogeneous integrated circuits that employ voltage booster circuits (e.g., inductor-based pumps or other suitable step-up voltage circuits of one or more types that differ from charge pumps) to boost voltage levels to requisite voltage levels. For example, in one embodiment, a heterogeneous integrated circuit of the present technology can include (a) one or more first dies of a first type and (b) a second die of a second type different from the first type. The one or more first dies can be integrated with (e.g., stacked on, bonded to, interconnected with) the second die. The heterogeneous integrated circuit can further include an inductor-based pump. The inductor-based pump can include (i) an inductor positioned within the second die, (ii) an input configured to receive a first voltage, and (iii) an output coupled to the first die(s). In some embodiments, the input can be positioned within the second die. In these and other embodiments, the inductor-based pump can be configured to (a) boost the first voltage to a second voltage greater than the first voltage and (b) output the second voltage at the output.

In some embodiments, an output of the inductor-based pump can be positioned within the second die. In these embodiments, the heterogeneous integrated circuit can include a through-silicon via (TSV) that (a) extends between the second die and the one or more first dies and (b) couples the output of the inductor-based pump to the one or more first dies such that the second voltage can be supplied to-and used by-the one or more first dies. As an example, an entirety of the inductor-based pump can be positioned within the second die, and/or the inductor-based pump can be configured to fully or entirely generate the second voltage within the second die. Continuing with this example, the inductor-based pump can generate the second voltage at the second die, and the heterogeneous integrated circuit can supply the second voltage to the one or more first dies via the TSV.

In other embodiments, a portion of the inductor-based pump can be positioned within the one or more first dies. In these embodiments, the heterogeneous integrated circuit can include a TSV that (a) extends between the second die and the one or more first dies and (b) couples the portion of the inductor-based pump positioned within the one or more first dies to the inductor of the inductor-based pump positioned within the second die. As an example, the inductor-based pump can generate the second voltage at the one or more first dies (e.g., such that an output of the inductor-based pump is positioned within one or more dies).

Historically, use of inductor-based pumps has been disfavored because of their relatively large size in comparison to charge pumps and other converters. For example, because inductors are relatively large circuit components, implementing such inductors into certain dies (e.g., memory dies, such as DRAM dies or NAND dies) with the other circuit components of an inductor-based pump has proven challenging (especially as die sizes have decreased) because implementation (i) can often require complicated and costly die designs/layouts and/or (ii) can significantly reduce the amount of available space for other die components. Heterogeneous integrated circuits, however, commonly include an interface die (or other die) that includes a large amount of spare or unused space. Several embodiments of the present technology therefore leverage the spare/unused space in an interface die (or other die) to employ inductor-based pumps for dies integrated with the interface die, such as by implementing at least part of the inductor-based pumps (e.g., the inductor) in the interface die.

The present technology is therefore expected to offer several advantages over heterogeneous integrated circuits (or other dies/circuits) that employ charge pumps for boosting voltage levels supplied by power supplies. For example, energy losses in inductor-based pumps are typically less than energy losses that occur when charging and discharging capacitors of a charge pump. As such, heterogeneous integrated circuits of the present technology that employ inductor-based pumps for boosting voltage levels supplied by power supplies are expected to be more energy efficient than heterogeneous integrated circuits that employ charge pumps for boosting such voltage levels. As another example, in comparison to charge pumps, inductor-based pumps can often handle higher output currents. Therefore, heterogeneous integrated circuits of the present technology that employ inductor-based pumps are expected to be more suitable for use in power-hungry applications than heterogeneous integrated circuits that employ charge pumps. As still another example, in comparison to charge pumps, output voltages of inductor-based pumps are relatively stable, even under varying load conditions. Thus, the risk of reliability issues occurring in heterogeneous integrated circuits of the present technology as a result of unstable output voltages from the inductor-based pumps is expected to be less than the risk of reliability issues occurring in heterogeneous integrated circuits that employ charge pumps.

FIG. 1 is a partially schematic, cross-sectional side view of a heterogeneous integrated circuit 130 configured in accordance with various embodiments of the present technology. As shown, the heterogeneous integrated circuit 130 includes a plurality of first dies 134 (e.g., first chips, first circuits) and a second die 132 (e.g., second chip, second circuit). The plurality of first dies 134 are identified individually in FIG. 1 as first dies 134a-134f. Although six first dies 134 are shown in the illustrated embodiment, heterogeneous integrated circuits configured in accordance with other embodiments of the present technology can include any number of first dies, such as one, two, three, four, five, or more than six first dies. Additionally, or alternatively, although shown with one second die 132 in the illustrated embodiment, heterogeneous integrated circuits configured in accordance with other embodiments of the present technology can include more than one second die.

As shown in FIG. 1, the first dies 134a-134f are arranged in a stack 136 positioned over (e.g., bonded to, carried by) the second die 132. Each of the first dies 134a-134f is further coupled to the second die 132 via one or more through-silicon vias 138 (“TSVs 138”). The TSVs 138 allow each of the first dies 134a-134f of the stack 136 to communicate data, such as (a) between one of the first dies 134a-134f and the second die 132, (b) between two or more of the first dies 134a-134f, and/or (c) between one or more of the first dies 134a-134f and an external device communicably coupled to the one or more of the first dies 134a-134f via the second die 132. Although shown as arranged in a single stack 136 in FIG. 1, in other embodiments of the present technology, the first dies 134a-134f can be arranged in multiple stacks positioned over the second die 132. In these and other embodiments, various ones of the first dies 134a-134f can be arranged (a) side-by-side (or laterally offset) from various other ones of the first dies 134a-134f and/or (b) side-by-side (or laterally offset) from the second die 132. Other configurations of the first dies 134a-134f relative to the second die 132 and/or to each other are of course possible and within the scope of the present technology. For example, the second die 132 can be positioned on or over all or a subset of the first dies 134a-134f (e.g., such that the second die 132 is stacked on or carried by all or the subset of the first dies 134a-134f).

In some embodiments, the first dies 134a-134f include a first type of die. For example, one or more of the first dies 134a-134f can be memory dies that include a plurality of memory cells for storing data. As specific examples, all or a first subset of the first dies 134a-134f can be volatile memory dies (e.g., DRAM dies), all or a second subset of the first dies 134a-134f can be non-volatile memory dies (e.g., NAND dies), and/or all or a third subset of the first dies 134a-134f can be combination dies (e.g., having volatile and non-volatile storage elements). In these and other embodiments, one or more of the first dies 134a-134f can be non-memory dies and/or another suitable type of die.

The second die 132 can be a second type of die (e.g., different from the first type of die). For example, the second die 132 can be an interface die (also referred to herein as a “base die,” a “logic die,” and the like). In these and other embodiments, the second die 132 can be an integrated circuit, an application processor, or a host device (e.g., a CPU, GPU, TPU, or other suitable type of controller, microcontroller, processor, or microprocessor).

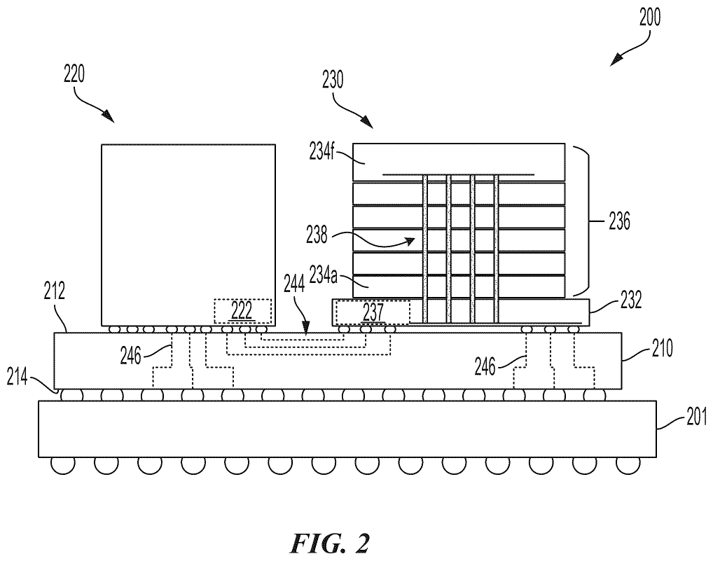

FIG. 2 is a partially schematic, cross-sectional side view of a system-in-package (SiP) device 200 that includes a heterogeneous integrated circuit 230 configured in accordance with various embodiments of the present technology. The heterogeneous integrated circuit 230 can be an example of the heterogeneous integrated circuit 130 of FIG. 1 and/or other heterogeneous integrated circuits of the present technology. As shown, the SiP device 200 also includes an interposer 210 (or any other suitable base substrate) that is carried by a package substrate 201. The SiP device 200 further includes a host device 220. The host device 220 and the heterogeneous integrated circuit 230 are each carried by and electrically coupled to (e.g., integrated with) an upper surface 212 of the interposer 210. The host device 220 (e.g., a GPU, CPU, TPU, and/or any other suitable processing unit) can include, among other features, a register and one or more levels of cache (e.g., an L1 cache, an L2 cache, and the like).

The heterogeneous integrated circuit 230 of the illustrated embodiment can be configured as an HBM cube (also referred to herein as an “HBM device”). More specifically, the heterogeneous integrated circuit 230 can include an interface die 232, one or more memory dies 234 (identified individually in FIG. 2 as memory dies 234a-234f) carried by the interface die 232, and one or more through-silicon vias 238 (“TSVs 238”) coupled to the interface die 232 and each of the memory dies 234. In the illustrated embodiment, the memory dies 234 are arranged in a stack 236. The TSVs 238 allow each of the memory dies 234a-234f to communicate data (e.g., between the memory dies 234a-234f and the interface die 232).

The interface die 232 can communicate data to and from the host device 220. For example, a physical layer 222 in the host device 220 can be coupled to one or more route lines 244 formed in the interposer 210. In turn, the route lines 244 can be coupled to a physical layer 237 in the heterogeneous integrated circuit 230 (e.g., in the interface die 232). As a result, the interface die 232 can be communicably coupled to the host device 220 via the route lines 244. The route lines 244 can provide a high-bandwidth channel through the interposer 210. Thus, the heterogeneous integrated circuit 230 can expand an amount of memory that is accessible to the host device 220 via a high-bandwidth communication channel.

As illustrated in FIG. 2, the interposer 210 can further include one or more interposer TSVs 246 extending between the upper surface 212 of the interposer 210 and a lower surface 214 of the interposer 210. The interposer TSVs 246 can allow the host device 220 and/or the heterogeneous integrated circuit 230 to send and/or receive signals (e.g., control signals, instructions, processing results, data, and the like) to and/or from, respectively, other devices coupled to the package substrate 201. In a specific, non-limiting example, the interposer TSVs 246 can allow the heterogeneous integrated circuit 230 to receive data from an external storage device (e.g., a NAND device) coupled to the package substrate 201.

Although a single heterogeneous integrated circuit 230 is shown in FIG. 2, SiP devices configured in accordance with other embodiments of the present technology can include more than one heterogeneous integrated circuit. For example, the heterogeneous integrated circuit 230 can be a first heterogeneous integrated circuit of the SiP device 200, and the SiP device 200 can further include a second heterogeneous integrated circuit. The second heterogeneous integrated circuit can be identical to or at least generally similar to the first heterogeneous integrated circuit. For example, the second heterogeneous integrated circuit can include a plurality of memory dies stacked on an interface die and communicably coupled with the interface die via TSVs. The interface die can include a physical layer that is communicably coupled to a physical layer of the host device 220, such as via one or more route lines 244 in the interposer 210. In other embodiments, the second heterogeneous integrated circuit can be different from the heterogeneous integrated circuit 230. Furthermore, although shown as arranged side-by-side (e.g., laterally offset) one another in the embodiment illustrated in FIG. 2, the heterogeneous integrated circuit 230 (or at least one or more of the memory dies 234a-234f) can be positioned on or over (e.g., carried by, stacked on) the host device 220 in other embodiments. Alternatively, the host device 220 can be positioned on or over (e.g., carried by, stacked on) one or more of the memory dies 234a-234f and/or the interface die 232.

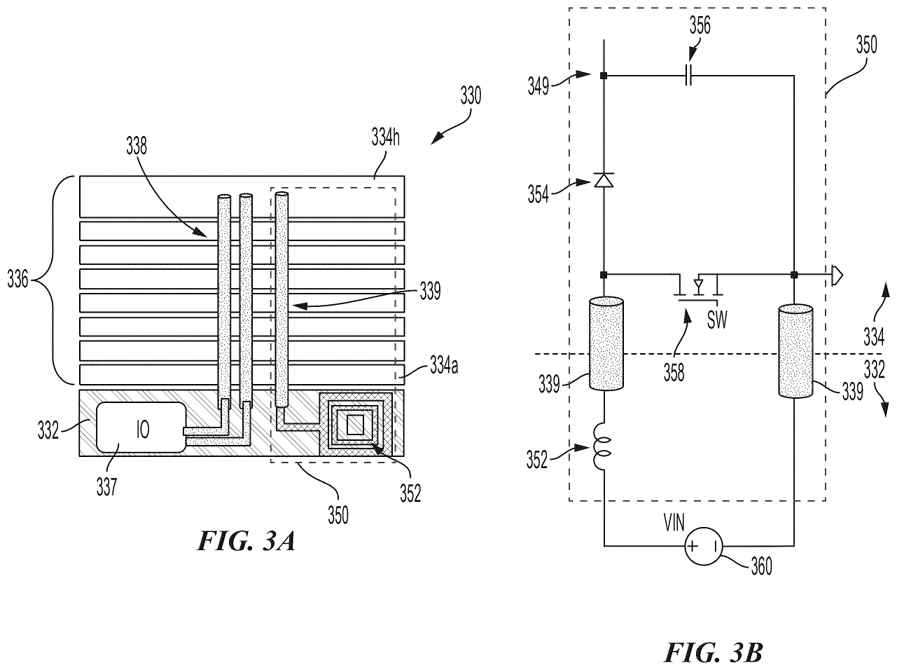

Many circuits (e.g., memory dies) of a heterogeneous integrated circuit can require voltage levels higher than those supplied by power supplies. For example, the first dies 134 of the heterogeneous integrated circuit 130 (FIG. 1) and/or the memory dies 234 of the heterogeneous integrated circuit 230 (FIG. 2) can be coupled to a power supply (not shown) configured to provide a first voltage (e.g., 1.8V). Continuing with this example, the first dies 134 and/or the memory dies 234 can require a second voltage higher than the first voltage, such as to perform data read, write, or erase operations. As a specific example, in embodiments in which the first dies 134 and/or the memory dies 234 include volatile memory dies (e.g., DRAM memory dies), the volatile memory dies 234 can require voltages on the order of 3.3V or another voltage level higher than the first voltage. As another specific example, in embodiments in which the first dies 134 and/or the memory dies 234a include non-voltage memory dies (e.g., NAND memory dies), the non-volatile memory dies 234 can require relatively high voltages, such as 12V or another voltage level higher than the first voltage. Therefore, as described in greater detail below with reference to FIGS. 3A-5B, heterogeneous integrated circuits (including the heterogeneous integrated circuit 130 of FIG. 1 and the heterogeneous integrated circuit 230 of FIG. 2) can employ inductor-based pumps to boost the first voltage supplied by power supplies coupled to the heterogeneous integrated circuits.

FIG. 3A is a partially schematic, cross-sectional side view of a heterogeneous integrated circuit 330 configured in accordance with various embodiments of the present technology. The heterogeneous integrated circuit 330 can be an example of the heterogeneous integrated circuit 130 of FIG. 1, an example of the heterogeneous integrated circuit 230 of FIG. 2, and/or an example of other heterogeneous integrated circuits of the present technology. As shown, the heterogeneous integrated circuit 330 includes a plurality of first dies 334 (identified individually in FIG. 3A as first dies 334a-334h) arranged in a stack 336 and positioned on or over a second die 332. As described above, the plurality of first dies 334 can include memory dies (e.g., volatile or DRAM memory dies, non-volatile or NAND memory dies) and/or other types of dies. Additionally, or alternatively, the second die 332 can be or include an interface die, an integrated circuit, an application processor, or a host device (e.g., a CPU, GPU, TPU, or other suitable type of controller, microcontroller, processor, or microprocessor).

The heterogeneous integrated circuit 330 can further include TSVs 338 that facilitate communicating data between (a) two or more of the first dies 334a-334h and/or (b) one or more of the first dies 334a-334h and (e.g., an input/output circuit 337 of) the second die 332. In these and other embodiments, the TSVs 338 can facilitate communicating data between one or more of the first dies 334a-334h and a device external to the heterogeneous integrated circuit 330, such as a host device (e.g., the host device 220 of FIG. 2) communicably coupled to the second die 332 and the plurality of first dies 334 via an interposer (not shown). For example, the input/output circuit 337 of the second die 332 can be identical to or at least generally similar to the physical layer 237 (FIG. 2) of the heterogeneous integrated circuit 230 (FIG. 2). Continuing with this example, the input/output circuit 337 can be communicably coupled to a physical layer of a host device via an interposer, and can facilitate transferring data between one or more of the first dies 334a-334h and the host device, via the second die 332.

In the illustrated embodiment, the heterogeneous integrated circuit 330 further includes an inductor-based pump 350 (also referred to herein as an “inductor-based DC booster,” a “DC booster,” a “heterogeneous DC booster,” a “voltage booster,” a “booster,” a “step-up voltage circuit,” a “boost converter,” and the like). As illustrated in FIG. 3A, the inductor-based pump 350 is coupled to the first dies 334a-334h via TSVs 339. FIG. 3B is a partially schematic diagram of the inductor-based pump 350 of FIG. 3A. Referring to FIG. 3B, the inductor-based pump 350 includes an inductor 352 (e.g., the inductor 352 illustrated in FIG. 3A), a diode 354, a capacitor 356, a switch 358, and a plurality of TSVs 339 (e.g., the TSVs 339 illustrated in FIG. 3A). As shown in FIG. 3A and FIG. 3B, the inductor 352 can be positioned in the second die 332. By contrast, as shown in FIG. 3B, the diode 354, the capacitor 356, and the switch 358 can be positioned in the first dies 334, and can be coupled to the inductor 352 via the TSVs 339.

In some embodiments, the diode 354, the capacitor 356, and/or the switch 358 can be positioned in one (e.g., only one) of the first dies 334a-334h, such as the first die 334a or the first die 334h. In other embodiments, the diode 354, the capacitor 356, and/or the switch 358 can be spread/distributed across multiple ones of the first dies 334a-334h. In still other embodiments, the inductor-based pump 350 can include multiple diodes 354, multiple capacitors 356, and/or multiple switches 358. In these embodiments, the diode(s) 354, the capacitor(s) 356, and/or the switch(es) 358 can be spread/distributed across all or a subset of the first dies 334a-334h. As a specific example, each of the first dies 334a-334h can include a unique/respective instance of one or more diodes 354, one or more capacitors 356, and/or one or more switches 358. In some embodiments, all or a subset of the first dies 334a-334h can include a unique/respective instance of an inductor (e.g., in lieu of the inductor 352). Continuing with this example, all or the subset of the first dies 334a-334h can include a unique/respective instance of an inductor-based pump (e.g., in lieu of the inductor-based pump 350).

In the embodiment illustrated in FIG. 3B, the inductor 352 is coupled at a first end to (e.g., a positive terminal of) a power supply 360. In some embodiments, the first end of the inductor 352 and/or the power supply 360 (e.g., the positive terminal of the power supply) can correspond to an input of the inductor-based pump 350. The second end of the inductor 352 is coupled at a second end to (e.g., an anode of) the diode 354 via a TSV 339 extending between the second die 332 and one or more of the first dies 334. In turn, the diode 354 couples the second end of the inductor 352 to a first plate of the capacitor 356. In some embodiments, the first plate of the capacitor 356 and/or the diode 354 (e.g., the cathode of the diode) can correspond to an output 349 of the inductor-based pump 350. A second plate of the capacitor 356 is coupled (i) to a signal ground connection and/or (ii) to the power supply 360 via another TSV 339. The switch 358 selectively couples (a) the second end of the inductor 352 and the diode 354 to (b) the signal ground connection, the second plate of the capacitor 356, and/or (e.g., the negative terminal of) the power supply 360. More specifically, the switch 358 is illustrated as an NMOS transistor having (i) a drain coupled to the anode of the diode 354 and the second end of the inductor 352; (ii) a source coupled to the ground connection, the second plate of the capacitor 356, and/or the power supply 360; and (iii) a gate configured to receive a switch signal SW that is usable to selectively activate the switch 358. The switch 358 of the inductor-based pump 350 can be another suitable type of switch in other embodiments of the present technology. Additionally, or alternatively, the diode 354 can be configured as a switch in some embodiments that is selectively activated to charge the capacitor 356 and/or selectively deactivated to prevent the capacitor 356 from discharging through the power supply 360 and/or the switch 358.

Operation of the inductor-based pump 350 will now be described. The power supply 360 can be configured to supply a first voltage (e.g., 1.8V or another suitable voltage) to an input of the inductor-based pump 350 (e.g., the first end of the inductor 352). While the switch 358 is open (e.g., deactivated, such as by de-asserting the switch signal SW or leaving the switch signal SW de-asserted), a relatively small amount of current flows (a) from the power supply 360 and (b) through the inductor 352 and the diode 354, allowing the capacitor 356 to charge. When the switch 358 is closed (e.g., activated, such as by asserting the switch signal SW), the switch 358 creates a short such that a relatively large amount of current flows from the power supply 360, through the inductor 352, and through the switch 358. The increase in the amount of current flowing through the inductor 352 when the switch 358 is closed expands a magnetic field generated by the inductor 352 such that the inductor 352 stores energy. At this time, the polarity of the inductor 352 is opposite the power supply 360 because it is consuming energy, meaning the voltage across the inductor 352 is negative with respect to the first voltage supplied at the input of the inductor-based pump 350 by the power supply 360.

When the switch 358 is thereafter opened (e.g., deactivated, such as by de-asserting the switch signal SW or leaving the switch signal SW de-asserted), the amount of current flowing through the inductor 352 decreases, which collapses the magnetic field generated by the inductor 352. While the magnetic field collapses, energy stored in the inductor 352 is released, and the polarity of the inductor 352 changes to match the power supply 360, meaning that the voltage across the inductor 352 is positive with respect to the first voltage supplied by the power supply 360. Because the inductor 352 is in series with the power supply 360, the voltage across the inductor 352 is added to the first voltage supplied by the power supply 360. In turn, the capacitor 356 is charged to a voltage that is greater than the first voltage supplied by the power supply 360. When the capacitor 356 is charged to a voltage greater than the first voltage supplied by the power supply 360, the diode 354 prevents the capacitor 356 from discharging through the power supply 360 (e.g., when the switch 358 is open) and/or the switch 358 (e.g., when the switch 358 is closed).

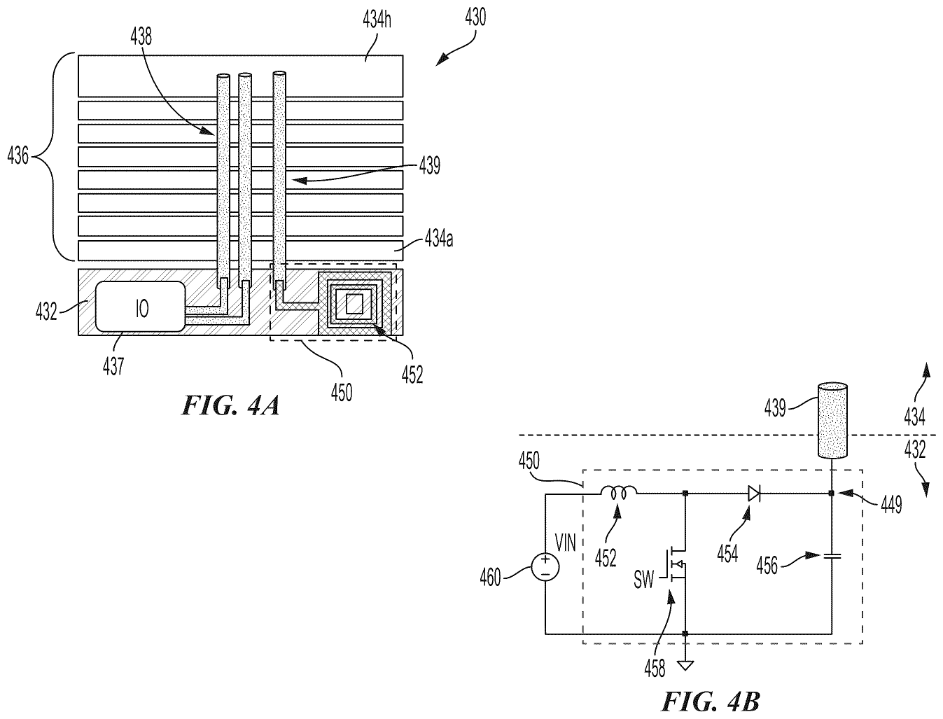

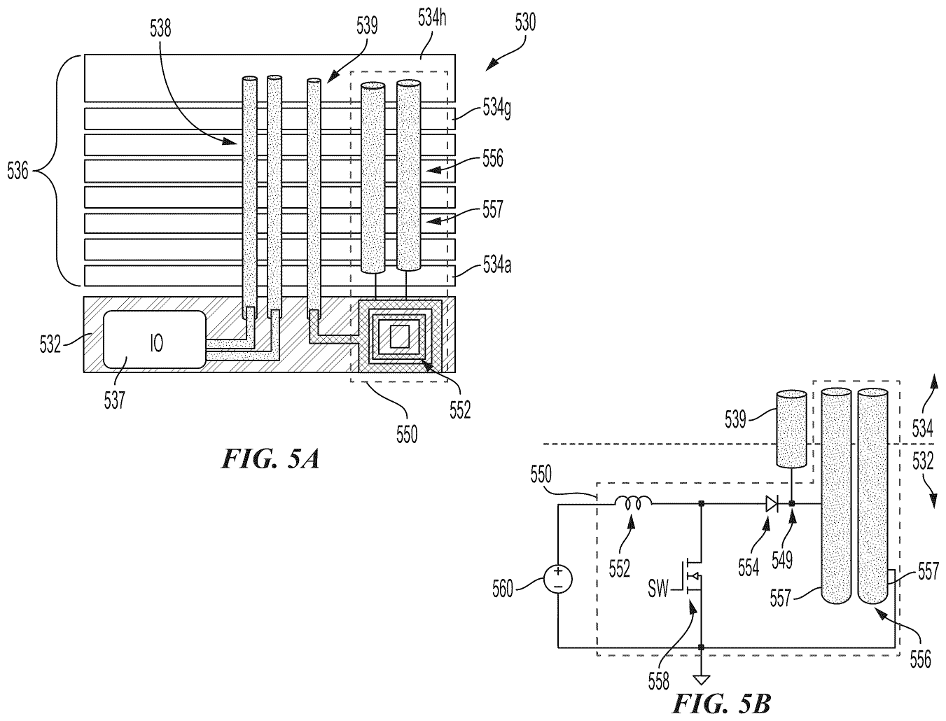

The voltage across the capacitor 356 can continue to increase as the switch 358 is sequentially turned on and off. The voltage on the capacitor 356 will continue to increase (e.g., toward a second voltage, such as 3.3V, 12V, or another suitable voltage level) until the inductor-based pump 350 reaches equilibrium (e.g., a state of the inductor-based pump 350 when the rate at which the inductor 352 transfers energy to the capacitor 356 equals the rate at which the capacitor 356 discharges energy to a load, such as a component of one of the one or more first dies 334a-334h (not shown)) coupled to the output 349 of the inductor-based pump 350. Because the capacitor 356 and the output 349 of the inductor-based pump 350 are positioned on one or more of the first dies 334a-334h (as opposed to on the second die 332), the second voltage is generated on the one or more first dies 334a-334h and is not seen by the second die 332. This differs from other embodiments of the present technology described below with reference to FIGS. 4A-5B. The second voltage output by the inductor-based pump 350 at the capacitor 356 can depend at least in part on the inductance of the inductor 352 and/or the rate at which the switch 358 is toggled on and off (e.g., using the switch signal SW). In this manner, the heterogeneous integrated circuit 330 can employ the inductor-based pump 350 to step up (i) the first voltage supplied by the power supply 360 at an input of the inductor-based pump 350 to (ii) a second voltage at an output of the inductor-based pump 350 that is usable by the first dies 334a-334h.

FIG. 4A is a partially schematic, cross-sectional side view of another heterogeneous integrated circuit 430 configured in accordance with various embodiments of the present technology. The heterogeneous integrated circuit 430 can be an example of the heterogeneous integrated circuit 130 of FIG. 1, an example of the heterogeneous integrated circuit 230 of FIG. 2, and/or an example of other heterogeneous integrated circuits of the present technology. As shown, the heterogeneous integrated circuit 430 is generally similar to the heterogeneous integrated circuit 330 of FIG. 3A. For example, the heterogeneous integrated circuit 430 includes a plurality of first dies 434 (identified individually in FIG. 4A as first dies 434a-434h) arranged in a stack 436 and positioned on or over a second die 432. The plurality of first dies 434 can include memory dies (e.g., volatile or DRAM memory dies, non-volatile or NAND memory dies) and/or other types of dies. Additionally, or alternatively, the second die 432 can be or include an interface die, an integrated circuit, an application processor, or a host device (e.g., a CPU, GPU, TPU, or other suitable type of controller, microcontroller, processor, or microprocessor).

The heterogeneous integrated circuit 430 can further include TSVs 438 that facilitate communicating data between (a) two or more of the first dies 434a-434h and/or (b) one or more of the first dies 434a-434h and (e.g., an input/output circuit 437 of) the second die 432. In these and other embodiments, the TSVs 438 can facilitate communicating data between one or more of the first dies 434a-434h and a device external to the heterogeneous integrated circuit 430, such as a host device (e.g., the host device 220 of FIG. 2) communicably coupled to the second die 432 and the plurality of first dies 434 via an interposer (not shown).

In the illustrated embodiment, the heterogeneous integrated circuit 430 further includes an inductor-based pump 450. As illustrated in FIG. 4A, the inductor-based pump 450 is coupled to the first dies 434a-434h via TSVs 439. FIG. 4B is a partially schematic diagram of the inductor-based pump 450 of FIG. 4A. Referring to FIG. 4B, the inductor-based pump 450 is generally similar to the inductor-based pump 350 of FIG. 3B in that the inductor-based pump 450 includes an inductor 452 (e.g., the inductor 452 illustrated in FIG. 4A), a diode 454, a capacitor 456, and a switch 458. In addition, as shown in FIGS. 4A and 4B, the inductor 452 of the inductor-based pump 450 can be positioned in the second die 432. In contrast with the inductor-based pump 350 of FIG. 3B, however, the diode 454, the capacitor 456, and the switch 458 of the inductor-based pump 450 of FIG. 4B can also be positioned in the second die 432 (as opposed to in one or more of the first dies 434). For example, an output 449 of the inductor-based pump 450 can be positioned within the second die 432 of the heterogeneous integrated circuit 430. As a specific example, an entirety of the inductor-based pump 450 can be positioned within the second die 432 of the heterogeneous integrated circuit 430.

Operation of the inductor-based pump 450 is generally similar to operation of the inductor-based pump 350 described above with reference to FIGS. 3A and 3B. For example, the inductor-based pump 450 (a) can be coupled to a power supply 460 that is configured to supply a first voltage (e.g., 1.8V or another suitable voltage) to an input of the inductor-based pump 450 (e.g., the first end of the inductor 452), and (b) can be configured to boost or step up the first voltage toward a second voltage (e.g., 3.3V, 12V, or another suitable voltage) by toggling the switch 458 on and off to charge the capacitor 456. Because the capacitor 456 and the output 449 of the inductor-based pump 450 are positioned on the second die 432 (as opposed to on one or more of the first dies 434a-434h), the second voltage can be (e.g., fully or entirely) generated on the second die 432. Thus, as the capacitor 456 is charged toward the second voltage, the capacitor 456 can be discharged via a TSV 439 that is (a) coupled to the capacitor 456 at the output 449 of the inductor-based pump 450 and (b) extends between the second die 432 and one or more of the first dies 434. In this manner, the heterogeneous integrated circuit 430 can employ the inductor-based pump 450 to (i) step up the first voltage supplied by the power supply 460 at the input of the inductor-based pump 450 to (ii) a second voltage at the output 449 of the inductor-based pump 450 that is (a) usable by the first dies 434a-434h and (b) supplied or distributed to the first dies 434a-434h via the TSV 439.

FIG. 5A is a partially schematic, cross-sectional side view of still another heterogeneous integrated circuit 530 configured in accordance with various embodiments of the present technology. The heterogeneous integrated circuit 530 can be the heterogeneous integrated circuit 130 of FIG. 1, the heterogeneous integrated circuit 230 of FIG. 2, or another heterogeneous integrated circuit of the present technology. As shown, the heterogeneous integrated circuit 530 is generally similar to the heterogeneous integrated circuit 330 of FIG. 3A and the heterogeneous integrated circuit 430 of FIG. 4A. For example, the heterogeneous integrated circuit 530 includes a plurality of first dies 534 (identified individually in FIG. 5A as first dies 534a-534h) arranged in a stack 536 and positioned on or over a second die 532. The plurality of first dies 534 can include memory dies (e.g., volatile or

DRAM memory dies, non-volatile or NAND memory dies) and/or other types of dies. Additionally, or alternatively, the second die 532 can be or include an interface die, an integrated circuit, an application processor, or a host device (e.g., a CPU, GPU, TPU, or other suitable type of controller, microcontroller, processor, or microprocessor).

The heterogeneous integrated circuit 530 can further include TSVs 538 that facilitate communicating data between (a) two or more of the first dies 534a-534h and/or (b) one or more of the first dies 534a-534h and (e.g., an input/output circuit 537 of) the second die 532. In these and other embodiments, the TSVs 538 can facilitate communicating data between one or more of the first dies 534a-534h and a device external to the heterogeneous integrated circuit 530, such as a host device (e.g., the host device 220 of FIG. 2) communicably coupled to the second die 532 and the plurality of first dies 534 via an interposer (not shown).

In the illustrated embodiment, the heterogeneous integrated circuit 530 further includes an inductor-based pump 550. FIG. 5B is a partially schematic diagram of the inductor-based pump 550 of FIG. 5A. Referring to FIG. 5B, the inductor-based pump 550 is generally similar to the inductor-based pump 450 of FIG. 4B. For example, the inductor-based pump 550 includes an inductor 552, a diode 554, a capacitor 556, and a switch 558. In addition, as shown in FIGS. 5A and 5B, the inductor 552, the diode 554, and the switch 558 of the inductor-based pump 550 can be positioned in the second die 532. Additionally, or alternatively, an output 549 of the inductor-based pump 550 can be positioned in the second die 532.

In contrast with the inductor-based pump 450 of FIG. 4B, however, the capacitor 556 is formed of two or more TSVs 557. In some embodiments, the TSVs 557 can be positioned close enough to one another to form a metal-insulator-metal capacitor. As shown in FIGS. 5A and 5B, the TSVs 557 can extend between the second die 532 and one or more of the first dies 534. For example, the TSVs 557 can extend between the second die 532 and the first die 534h. As another example, the TSVs 557 can extend between the second die 532 and one of the first dies 534a-534g positioned lower in the stack 536 than the first die 534h. In other embodiments, the TSVs 557 can be positioned in the second die 532 without extending into the first dies 534. For example, the TSVs 557 can extend at least partway through the second die 532 but not into the first die 534a. Additionally, or alternatively, although one set of the TSVs 557 are shown in FIGS. 5A and 5B, the inductor-based pump 550 can include a plurality of sets of the TSVs 557 in other embodiments of the present technology. For example, the inductor-based pump 550 can include multiple sets of the TSVs 557 that are arranged in series or in parallel with one another (e.g., to achieve a desired capacitance).

Operation of the inductor-based pump 550 is generally similar to operation of the inductor-based pump 450 described above with reference to FIGS. 4A and 4B. For example, the inductor-based pump 550 (a) can be coupled to a power supply 560 that is configured to supply a first voltage (e.g., 1.8V or another suitable voltage) to an input of the inductor-based pump 550 (e.g., the first end of the inductor 552), and (b) can be configured to boost or step up the first voltage toward a second voltage (e.g., 3.3V, 12V, or another suitable voltage) by toggling the switch 558 on and off to charge the capacitor 556. As the capacitor 556 is charged toward the second voltage, the capacitor 556 can be discharged via a TSV 539 that is (a) coupled to the capacitor 556 and the output 549 of the inductor-based pump 550, and (b) extends between the second die 532 and one or more of the first dies 534. In this manner, the heterogeneous integrated circuit 530 can employ the inductor-based pump 550 to (i) step up the first voltage supplied by the power supply 560 to the input of the inductor-based pump 550 to (ii) a second voltage at the output of the inductor-based pump 550 that is (a) usable by the first dies 534a-534h and (b) supplied to the first dies 534a-534h via the TSV 539.

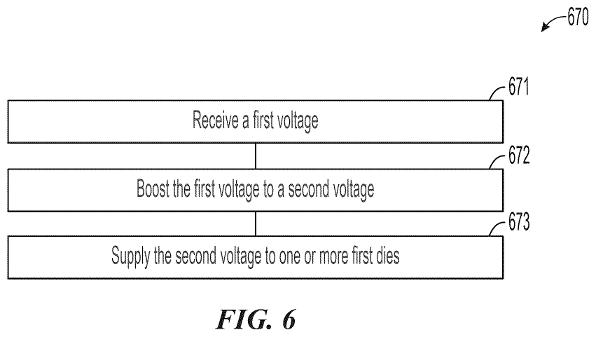

FIG. 6 is a flow diagram illustrating a method 670 of operating a heterogeneous integrated circuit in accordance with various embodiments of the present technology. The method 670 is illustrated as a series of block 671-673 or steps. All or a subset of one or more of the blocks 671-673 can be executed by devices or components of a heterogeneous integrated circuit configured in accordance with various embodiments of the present technology, such as one or more first dies (e.g., memory dies) and/or one or more second dies (e.g., host devices, such as CPUs, GPUs, or TPUs; ICs; and/or base/interface dies) integrated with the one or more first dies. For example, all or a subset of one or more of the blocks 671-673 can be executed by a step-up voltage circuit (e.g., an inductor-based pump) at least partially positioned (i) in the one or more first dies and/or (ii) in the one or more second dies. All or a subset of one or more of the blocks 671-673 of the method 670 can be executed in accordance with the description of FIGS. 1-5B above and/or with the description below.

The method 670 begins at block 671 by receiving a first voltage. Receiving the first voltage can include receiving the first voltage at an input of a step-up voltage circuit of the heterogeneous integrated circuit. As described above, the step-up voltage circuit can be an inductor-based pump. Additionally, or alternatively, the step-up voltage circuit can be at least partially positioned within a second die of a heterogeneous integrated circuit that includes one or more first dies integrated with the second die. In these and other embodiments, the step-up voltage circuit can be at least partially positioned within the one or more first dies. For example, a first part of the step-up voltage circuit can be positioned within the second die, and a second part of the step-up voltage circuit can be positioned within the one or more first dies. The second part of the step-up voltage circuit can be coupled to the first part of the step-up voltage circuit using a TSV, such as a TSV that extends between the second die and the one or more first dies.

At block 672, the method 670 continues by boosting the first voltage to a second voltage. Boosting the first voltage to the second voltage can include boosting the first voltage to the second voltage using the step-up voltage circuit. Additionally, or alternatively, boosting the first voltage to the second voltage can include generating the second voltage at the second die, such as at an output of the step-up voltage circuit positioned within the second die. In these and other embodiments, boosting the first voltage to the second voltage can include generating the second voltage at the one or more first dies, such as at an output of the step-up voltage circuit positioned within the one or more first dies.

At block 673, the method 670 continues by supplying the second voltage to the one or more first dies. In some embodiments, supplying the second voltage to the one or more first dies can include supplying the second voltage to the one or more first dies using a TSV, such as a TSV that couples the one or more first dies to an output of the step-up voltage circuit.

Although the blocks 671-673 of the method 670 are described and illustrated in a particular order, the method 670 of FIG. 6 is not so limited. In other embodiments, all or a subset of one or more of the blocks 671-673 of the method 670 can be performed in a different order. In these and other embodiments, all or a subset of any of the blocks 671-673 can be performed before, during, and/or after all or a subset of any of the other blocks 671-673. Furthermore, a person skilled in the art will readily appreciate that the method 670 can be altered and still remain within these and other embodiments of the present technology. For example, all or a subset of one or more of the block 671-673 can be omitted and/or repeated in some embodiments.

### CONCLUSION

From the foregoing, it will be appreciated that specific embodiments of the technology have been described herein for purposes of illustration, but well-known structures and functions have not been shown or described in detail to avoid unnecessarily obscuring the description of the embodiments of the technology. To the extent any material incorporated herein by reference conflicts with the present disclosure, the present disclosure controls. Where the context permits, singular or plural terms may also include the plural or singular term, respectively. Moreover, unless the word “or” is expressly limited to mean only a single item exclusive of the other items in reference to a list of two or more items, then the use of “or” in such a list is to be interpreted as including (a) any single item in the list, (b) all of the items in the list, or (c) any combination of the items in the list. Furthermore, as used herein, the phrase “and/or” as in “A and/or B” refers to A alone, B alone, and both A and B. Additionally, the terms “comprising,” “including,” “having,” and “with” are used throughout to mean including at least the recited feature(s) such that any greater number of the same features and/or additional types of other features are not precluded. Further, the terms “approximately” and “about” are used herein to mean within at least within 10% of a given value or limit. Purely by way of example, an approximate ratio means within 10% of the given ratio.

In the detailed description of the present technology provided above, the term “through-silicon via” or “TSV” is used to generically describe an interconnect or via structure (a) that is used to electrically couple stacked substrates (e.g., one or more first dies and/or one or more second dies) to one another and/or (b) that is usable to vertically transmit electrical signals at least partway up or down a stack of substrates. In some embodiments, one or more substrates of a stack can, but need not, be formed of silicon. For example, the term “through-silicon via” or “TSV” as used herein can be used to describe an electrical connection that extends vertically at least partially through a substrate formed of silicon or another suitable material other than silicon. Thus, the term “through-silicon via” or “TSV” as used herein should be interpreted broadly to include an interconnect or via structure that extends vertically at least partially through one or more substrates formed of silicon or another suitable material.

Several implementations of the disclosed technology are described above in reference to the figures. The computing devices on which the described technology may be implemented can include one or more central processing units, memory, input devices (e.g., keyboard and pointing devices), output devices (e.g., display devices), storage devices (e.g., disk drives), and network devices (e.g., network interfaces). The memory and storage devices are computer-readable storage media that can store instructions that implement at least portions of the described technology. In addition, the data structures and message structures can be stored or transmitted via a data transmission medium, such as a signal on a communications link. Various communications links can be used, such as the Internet, a local area network, a wide area network, or a point-to-point dial-up connection. Thus, computer-readable media can comprise computer-readable storage media (e.g., “non-transitory” media) and computer-readable transmission media.

From the foregoing, it will also be appreciated that various modifications may be made without deviating from the disclosure or the technology. For example, one of ordinary skill in the art will understand that various components of the technology can be further divided into subcomponents, or that various components and functions of the technology may be combined and integrated. In addition, certain aspects of the technology described in the context of particular embodiments may also be combined or eliminated in other embodiments.

Furthermore, although advantages associated with certain embodiments of the technology have been described in the context of those embodiments, other embodiments may also exhibit such advantages, and not all embodiments need necessarily exhibit such advantages to fall within the scope of the technology. Accordingly, the disclosure and associated technology can encompass other embodiments not expressly shown or described herein.

We claim:

1. A heterogeneous device, comprising:
one or more first dies of a first type;
a second die of a second type different from the first type, wherein the one or more first dies are integrated with the second die; and
an inductor-based pump having an inductor positioned within the second die, wherein the inductor-based pump includes (a) an input configured to receive a first voltage and (b) an output coupled to the one or more first dies, and wherein the inductor-based pump is configured to (i) boost the first voltage to a second voltage greater than the first voltage and (ii) output the second voltage at the output.

2. The heterogeneous device of claim 1, wherein the one or more first dies and the second die are arranged in a stack, wherein a part of the inductor-based pump is positioned within the one or more first dies, and wherein the heterogeneous device further includes a through-silicon via (TSV) that (i) extends between the second die and the one or more first dies and (ii) couples the part of the inductor-based pump to the inductor of the inductor-based pump.

3. The heterogeneous device of claim 2, wherein the inductor-based pump is configured to generate the second voltage within the one or more first dies.

4. The heterogeneous device of claim 1, wherein:
the one or more first dies and the second die are arranged in a stack;
the output of the inductor-based pump is positioned within the second die;
the inductor-based pump is configured to at least partially generate the second voltage within the second die; and
the heterogeneous device further includes a through-silicon via (TSV) that (i) extends between the second die and the one or more first dies, (ii) couples the output of the inductor-based pump to the one or more first dies, and (iii) is configured to supply the second voltage to the one or more first dies.

5. The heterogeneous device of claim 4, wherein the inductor-based pump is configured to generate the second voltage entirely within the second die.

6. The heterogeneous device of claim 1, wherein the inductor-based pump further includes a diode, a capacitor, and a switch.

7. The heterogeneous device of claim 6, wherein:
a first end of the inductor is coupled the input of the inductor-based pump;
a second end of the inductor is coupled to the capacitor via the diode; and
the switch is configured to selectively short the inductor-based pump such that current does not flow through the diode to the capacitor.

8. The heterogeneous device of claim 6, wherein the capacitor is formed by a plurality of through-silicon vias (TSVs) that extend at least partway between the second die and the one or more first dies.

9. The heterogeneous device of claim 1, wherein the one or more first dies include one or more memory dies.

10. The heterogeneous device of claim 9, wherein the one or more memory dies include one or more dynamic random-access memory (DRAM) dies.

11. The heterogeneous device of claim 9, wherein the one or more memory dies include one or more NAND memory dies.

12. The heterogeneous device of claim 1, wherein the second die includes an interface die, a logic die, or an application processor.

13. The heterogeneous device of claim 12, wherein the heterogeneous device includes a high-bandwidth memory cube.

14. The heterogeneous device of claim 1, wherein the second die includes a central processing unit (CPU), a graphics processing unit (GPU), or a tensor processing unit (TPU).

15. A method of operating a heterogeneous device including one or more first dies and a second die integrated with the one or more first dies, the method comprising:
receiving, at an input of a step-up voltage circuit, a first voltage, wherein the step-up voltage circuit is at least partially positioned within the second die;
boosting the first voltage to a second voltage using the step-up voltage circuit; and
supplying the second voltage to the one or more first dies.

16. The method of claim 15, wherein:
boosting the first voltage to the second voltage includes generating the second voltage at the second die; and
supplying the second voltage includes supplying the second voltage to the one or more first dies using a through-silicon via (TSV) that couples the one or more first dies to an output of the step-up voltage circuit.

17. The method of claim 15, wherein the step-up voltage circuit is at least partially positioned within the one or more first dies, wherein boosting the first voltage to the second voltage includes generating the second voltage at the one or more first dies, and wherein a first part of the step-up voltage circuit positioned within the second die is coupled to a second part of the step-up voltage circuit positioned within the one or more first dies using a through-silicon via (TSV) that extends between the second die and the one or more first dies.

18. A heterogeneous integrated circuit, comprising:
a first die;
a second die integrated with the first die, the second die including different circuitry from the first die; and
a voltage booster circuit at least partially positioned within the second die, wherein the voltage booster circuit (i) includes an input and an output and (ii) is configured to step-up a first voltage received at the input to a second, greater voltage at the output, and wherein the output is coupled to the first die such that the second voltage is usable by the first die.

19. The heterogeneous integrated circuit of claim 18, wherein:
the voltage booster circuit is at least partially positioned within the first die such that the voltage booster circuit is configured to generate the second voltage within the first die;
the first die and the second die are arranged in a stack;
the heterogeneous integrated circuit further includes a through-silicon via (TSV) that (a) extends between the first die and the second die and (b) couples the input of the voltage booster circuit to the output of the voltage booster circuit; and
the output of the voltage booster circuit is positioned within the first die.

20. The heterogeneous integrated circuit of claim 18, wherein:
an output of the voltage booster circuit is positioned within the second die;
the voltage booster circuit is configured to generate the second voltage within the second die;
the first die and the second die are arranged in a stack; and
the heterogeneous integrated circuit further includes a through-silicon via (TSV) that (a) extends between the first die and the second die and (b) couples the output of the voltage booster circuit to the first die.
